(19) United States
(12) Patent Application Publication
(10) Pub. No.: US 2010/0151072 A1
(43) Pub. Date: Jun. 17, 2010

(54) DIE PLATE AND METHOD FOR MANUFACTURE THEREOF

(75) Inventor: Jochen Scheurich, Niedernberg (DE)

Correspondence Address: BUSKOP LAW GROUP, P.C., 4511 Dacoma Street, HOUSTON, TX, 77092, US

(73) Assignee: AUTOMATIK PLASTICS MACHINERY GMBH, Grossostheim (DE)

(21) Appl. No.: 12/638,203

(22) Filed: Dec. 15, 2009

(30) Foreign Application Priority Data
Dec. 16, 2008 (DE) 102008062519.1

(51) Int. Cl. B29C 47/12; C23C 14/28

(52) U.S. Cl. 425/461; 427/597

(57) ABSTRACT

One or more methods for the manufacture of a die plate of an extruder of a pelletizer for thermoplastic material, with die orifice openings are provided. One or more of the methods can include providing a die plate blank having a die plate base material; producing a functional layer with a reinforcing material in at least one region on at least one side of the die plate blank, and applying the reinforcing material to the die plate base material in the region of the functional layer by laser dispersion.

### CROSS REFERENCE TO RELATED APPLICATIONS

The present application claims priority to and the benefit of co-pending German Patent Application No. 10 2008 062 519.1, filed on Dec. 16, 2008, entitled “Die Plate and Method for Manufacture Thereof”. This reference is hereby incorporated in its entirety.

### FIELD

The present embodiments generally relate to a method for the manufacture of a die plate of an extruder of a pelletizer for thermoplastic material, with die orifice openings, with the following steps: provision of a die plate blank of a die plate base material; production of a functional layer with a reinforcing material in at least one region on at least one side of the die plate blank, the reinforcing material being applied to the die plate base material in the region of the functional layer by laser dispersion; and application of the die orifice openings to the die plate. The invention further relates to a die plate with die orifice openings and a functional layer.

### BACKGROUND

A need exists for low cost, efficient method for the manufacture of a die plate as well as a corresponding die plate that provides a die plate having optimized thermal insulation properties and high wear resistance.

A need further exists for a method of manufacturing a die plate that has a maximized service life and that is simple to recondition.

The present embodiments meet these needs.

### BRIEF DESCRIPTION OF THE DRAWINGS

The detailed description will be better understood in conjunction with the accompanying drawings as follows:

FIG. 1 shows a schematic representation of the step of production of a functional layer by laser dispersion according to a preferred embodiment of the method according to the invention.

FIG. 2 shows a schematic sectional view of a die plate with a functional layer according to a preferred embodiment of the invention.

FIG. 3 shows a schematic sectional view of a die plate with a functional layer according to a preferred embodiment of the invention in the region of die orifice openings of the die plate.

FIG. 4 shows a schematic view of a die plate according to the invention in the installed state.

The present embodiments are detailed below with reference to the listed Figures.

### DETAILED DESCRIPTION OF THE EMBODIMENTS

Before explaining the present apparatus in detail, it is to be understood that the apparatus is not limited to the particular embodiments and that it can be practiced or carried out in various ways.

The present embodiments relate to a die plate for an extruder of a pelletizer for thermoplastic material and a method of manufacturing the same.

One or more embodiments of the method for manufacturing or making the die plate can include providing a die plate blank. The die plate blank can be made from a die plate base material

The method can also include producing a functional layer with a reinforcing material in at least one region on at least one side of the die plate blank. The reinforcing material can be applied to the die plate base material in the region of the functional layer by laser dispersion.

The die orifice openings can be applied to the die plate. For example, the die orifice openings can be applied to the die plate by drilling or eroding.

The die orifice openings can be applied to the die plate prior or subsequent to the production of the functional layer.

The die orifice openings can be applied to the die plate with certain cross-sectional profiles that have section-wise variations over the length of the die plate.

During the production of the functional layer by laser dispersion, the reinforcing material can be applied to the die plate base material through heating of at least the die plate base material. In one or more embodiments, the reinforcing material can be co-heated with the die plate base material.

At least the die plate base material can be heated by a laser beam and the reinforcing material can be applied to the die plate base material. For example, the reinforcing material can penetrate into the die plate base material, which has been heated and partially melted by the energy of the laser beam, and be distributed therein.

As such, this reinforcing material can be homogeneously embedded in the die plate base material. Consequently, a uniform functional layer which homogeneously provides both the properties of the die plate base material, e.g. metal material with the same coefficient of thermal expansion as the adjacent components of the pelletizer, and also the additional reinforcing and, as appropriate, also heat-insulating material properties of the reinforcing material (or, more generally: functional material), e.g. a ceramic material for enhanced resistance to wear and improved thermal insulation.

Accordingly, the reinforcing material can be applied to the base plate material by laser dispersion, which is easy to execute. The laser dispersion is a relatively simple and cost-effective manner to manufacture die plates with not only high thermal insulation but also high resistance to wear.

The laser dispersion makes it possible for the amount of heat applied to the manufactured die plate to be locally confined and therefore minimized, especially in the case of the section-wise laser dispersion.

In one or more embodiments, the die plate material can be provided with the functional layer section-wise in certain regions.

In one or more embodiments, at least one side of the die plate blank can be provided with a functional layer section-wise applied to at least one region. The laser dispersion of reinforcing material into the die plate material can help avoid any heat-induced warping of the manufactured die plate.

Furthermore, the embedding the reinforcing material in the die plate material according to the method of the invention facilitates the reconditioning of a die plate that has been manufactured by such a method. For example, if a portion of the functional layer has been ground down, the combined material properties of the functional layer (combination of the above-discussed material properties of the die plate base material and of the reinforcing material) can be maintained.

In addition, through adjustment of the parameters for laser dispersion, e.g. by changing the penetration depth of the laser in the base material, through suitable selection of the temperature range, through selection of the quantity and/or type of the reinforcing material or similar means, a simple means of flexibly selecting and adjusting the required parameters of the functional layer of the die plate can be provide. For example, the parameters of the laser dispersion can be adjusted to provide a functional layer with one or more desired thermal insulation properties and wear resistance properties.

In one or more embodiments, the production of the functional layer by laser dispersion can include applying the reinforcing material at least section-wise as a particle powder to the die plate base material and heating at least the die plate base material, allowing particles from the particle powder of the reinforcing material to become embedded in the die plate base material in the region of the heated functional layer.

In one or more embodiments, the reinforcing material can be heated along with the die plate base material.

In one or more embodiments, the particle powder can be applied to the die plate base material over the full area thereof, and at least one of the die plate base material and the particle powder of the reinforcing material can be heated section-wise by a laser beam.

In one or more embodiments, the production of the functional layer can take place by section-wise laser dispersion over at least one region of the side of the die plate base material. For example, a region of up to 5 mm in diameter can be heated by a laser beam.

In one or more embodiments, an area smaller than 5 mm can be heated by focusing of the laser beam.

In one more embodiments, the penetration depth of the laser beam into the die plate base material can be adjusted by focusing the laser beam and/or adjusting the intensity of the laser beam. For example, the penetration depth of the laser beam into the die plate base material can be adjusted to control the layer thickness of a formed functional layer.

In one or more embodiments, the reconditioning of a die plate can be facilitated by repeating the production of the functional layer several times. This can be carried out, for example, after a die plate manufactured by one or more embodiments of the method has been in service for a certain length of time, after which one or more functional layers formed by the laser dispersion has been worn down in use. In such a case, through renewed execution of laser dispersion or of the corresponding step of production of the functional layer, a new functional layer in the die plate base material can be formed. Furthermore, through an at least section-wise repetition of the step of production of the functional layer, it is possible, at least section-wise, additionally to influence, for example, the layer thickness, the layer width, and/or composition of the functional layer.

In general, through laser dispersion, such as through section-wise laser dispersion, it is possible for a certain region of the die plate base material to be subjected several times to the step of production of the functional layer, i.e. the production of the functional layer can be executed in a region several times in direct succession. This can enable, as appropriate, an additional accumulation of the reinforcing material, such as of particles of reinforcing material, in the die plate base material at the site that has been treated several times in direct succession, this making it possible for the material properties in said region to be adjusted and influenced over a still wider area of application.

The method according to the invention generally offers great advantages with regard to its flexibility and with regard to the possibility for material parameters to be selectively adjusted and produced through a combination of die plate base material and reinforcing material in the region of the functional layer of the produced die plate.

The die plate of an extruder of a pelletizer for thermoplastic material can have a die orifice opening. In at least one region, e.g. in a region of the die orifice openings that is swept by a knife when the pelletizer is in operation, at least one side of the die plate can be provided with a functional layer with a reinforcing material. The reinforcing material can be embedded in the die plate base material. The reinforcing material can also have heat-insulating properties. The die plate can also be provided with the functional layer over at least one entire side or over both sides.

According to the invention, therefore, the particular advantages of the combination of properties of the die plate base material and of the reinforcing material are obtained in the region of the provided functional layer of the die plate according to the invention. In particular, a die plate can have a homogeneous thermal insulation layer combined with resistance to wear in the region of the functional layer. In addition, differences in the coefficient of thermal expansion between the formed die plate and the other components of the pelletizer can be avoided.

In one or more embodiments, the reinforcing material in the form of particles can be embedded in the die plate base material in the region of the functional layer. Consequently, certain reinforcing materials can be used especially efficiently, and the structure of the die plate base material can be chemically not so influenced by the corresponding particles in contrast to a molecular inclusion of the reinforcing material in the region of the functional layer.

The material of the reinforcing material and/or the die plate can be chosen to maximize the homogeneity and suitability of the coefficients of thermal expansion of the die plate. In one or more embodiments the material of the die plate can be a metal or metal alloy. For example, the die plate can be steel or a steel alloy.

In one or more embodiments, the reinforcing material can be a ceramic material. For example, the reinforcing material can be ZrO2.

The reinforcing material can also be a carbide alloy material, such as cermet. A carbide alloy can provide a good adaptation of the thermal conductivity and thermal expansion properties of the die plate base material and/or to the materials of the other components of the pelletizer.

The functional layer of the die plate can have an average layer thickness (d) of about 3 mm or less. For example, the die plate can have an average layer thickness (d) of less than 1 mm. In one or more embodiments, the die plate can have an average layer thickness (d) of 0.5 mm or less. The layer thicknesses can allow a relatively long service life of the die plate. Furthermore, the thickness of the dies plate can allow the die plate to be reground.

The particles of the reinforcing material in the functional layer can have an average diameter in the range from 0.5 μm to 2.0 μm. The particle size allows good embedding in the die plate base material, it also being the case that the reinforcing and/or heat-insulating properties of the reinforcing material can be especially effectively exploited, because such particles allow a sufficiently large penetration of reinforcing material into the die plate base material.

The content by volume of the particles of the reinforcing material in the functional layer can range from about 5 vol. % to about 50 vol. %.

The functional layer can have a hardness in the range from about 1000 HV to about 1500 HV (Vickers hardness).

The coefficient of thermal expansion of the functional layer can be in a range from about 1 W/mK to about 2 W/mK.

The functional layer can have a coefficient of thermal expansion identical to that of the pure die plate base material or differing therefrom at least only in the range of +/−10%. This can further improve the thermal expansion properties of the die plate according to the invention, because the maximum homogeneity of the coefficient of thermal expansion can be provided across the entire die plate, including the functional layer.

The die plate can be manufactured by means of laser dispersion.

In general, all the advantages/features that have been described in connection with the method according to the manufacture of a die plate apply also, where applicable, to the die plate itself, and vice versa.

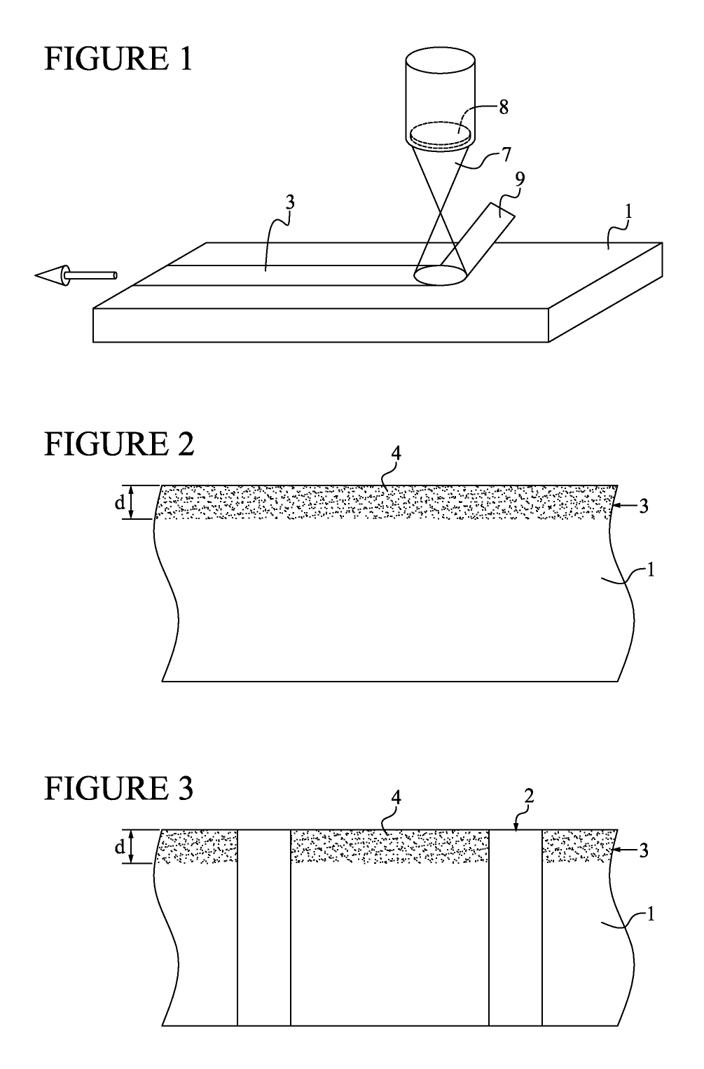

FIG. 1 shows a schematic representation of the execution of an embodiments of the method.

The method can include producing the functional layer using laser dispersion.

As schematically presented in FIG. 1, a laser beam 7, such as a laser beam from a Nd:YAG laser beam source, can be focused through a schematically indicated lens system 8 onto a certain region of the die plate base material of the die plate 1. The diameter of the region heated by the laser beam 7 can be up to 5 mm.

The method can also include applying particle powder of a reinforcing material section-wise in at least one region on at least one side of the die plate blank of the die plate 1. For example, the particle powder of the reinforcing material can be applied to the region of the die plate base material heated by the laser beam 7. The particle powder can be applied by a particle powder supply 9, which is schematically indicated in FIG. 1.

As such, the reinforcing material can be applied to the die plate base material in the region of the functional layer 3. The reinforcing material can penetrate into the die plate base material, which has been heated and partially melted by the energy of the laser beam 7. The reinforcing material can be distributed through out the die plate base material that has been heated and partially melted by the energy of the laser beam 7. Accordingly, the reinforcing material can be homogeneously embedded into the die plate base material and, consequently, in the functional layer 3. The process is here referred to as laser dispersion of the reinforcing material in the die plate base material.

If it is desired that the functional layer 3 should be applied to a larger region or to a region of an entire surface on one side of the die plate blank of the thus produced die plate 1, a correspondingly larger region can be processed section-wise by strip-wise laser dispersion, as described hereinbefore. The corresponding example of the feed motion of the future die plate 1 is indicated by the arrow on the left in FIG. 1.

FIG. 2 presents a schematic sectional view of a die plate 1 of an extruder of a pelletizer for thermoplastic material. The functional layer 3 is provided with particles 4 of the reinforcing material, the particles 4 being embedded in the die plate base material in the region of the functional layer 3. The embedding can be accomplished according to the invention by means of laser dispersion, as has been described hereinbefore.

The functional layer 3 can have an average layer thickness (d) of less than about 0.5 mm to about 3 mm. For example, the layer thickness (d) can range from about 0.3 mm to about 1 mm. The reinforcing material can be homogeneously distributed over the entire layer thickness (d) and embedded in the form of the particles 4, in the region of the functional layer 3.

FIG. 3 presents a schematic sectional view of a die plate 1 according to the invention in the region of the die orifice openings 2. The die orifice openings 2 can be applied to the die plate by one or method described herein. The die orifice openings can be applied, e.g. by drilling or eroding, to the die plate after production of the functional layer.

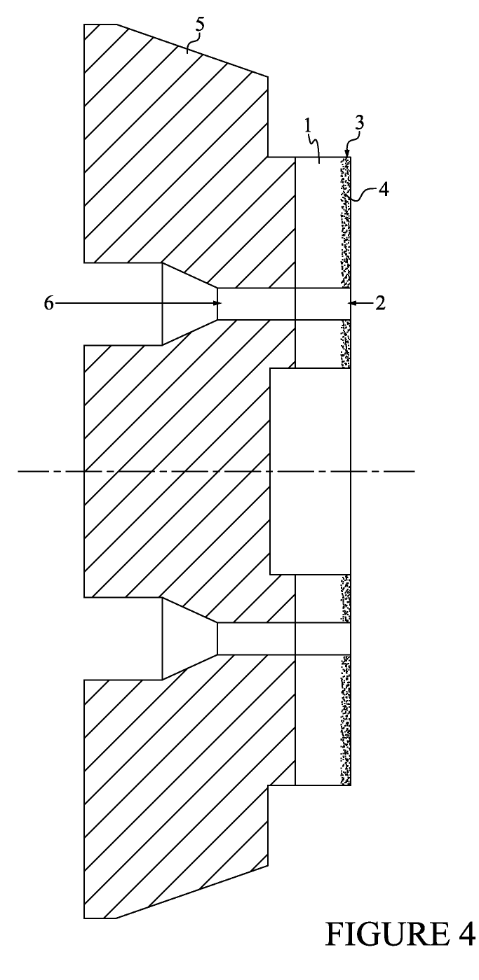

FIG. 4 presents a schematic representation of a die plate according to one or more embodiments of the invention in the installed state. The die plate 1 with the functional layer 3 and embedded particles 4 of the reinforcing material can be attached to an outlet region 5 of an extruder of a pelletizer. Such attachment can be accomplished, for example, by screwing or similar means (not shown in FIG. 4). Alternatively, however, the outlet region 5 and the die plate 1 can be produced in one piece, e.g. integrally formed. The molten thermoplastic material can be supplied through melt channels 6 to the die orifice openings 2 of the die plate 1. Upon issuing therefrom, the thermoplastic material can be cut off by a cutting device (not shown in FIG. 4), this resulting in the production of pellets from the thermoplastic material.

The functional layer 3 can be provided only in a region of the die plate 1, e.g. in the region of the die orifice openings 2, because that is the main region.

Conversely, FIG. 4 presents one or more embodiments in which a complete side of the die plate 1 is provided with the functional layer 3, this resulting in suitably homogeneous optimization especially of the thermal conductivity properties over the entire side of the thus formed die plate 1.

An arrangement of the kind presented in FIG. 4 can be employed, for example, in an underwater pelletizer.

While these embodiments have been described with emphasis on the embodiments, it should be understood that within the scope of the appended claims, the embodiments might be practiced other than as specifically described herein.

What is claimed is:

1. A method for the manufacture of a die plate of an extruder of a pelletizer for thermoplastic material, with die orifice openings, wherein the method comprises:
a. providing a die plate blank of a die plate base material;
b. producing a functional layer with a reinforcing material in at least one region on at least one side of the die plate blank, the reinforcing material being applied to the die plate base material in the region of the functional layer by laser dispersion; and
c. applying the die orifice openings to the die plate.

2. The method of claim 1, wherein the production of the functional layer by laser dispersion further comprises applying the reinforcing material at least section-wise as a particle powder to the die plate base material and heating at least the die plate at least in the region of the functional layer with the laser beam allowing the particles from the particle powder of the reinforcing material to embed in the die plate base material in the region of the heated functional layer.

3. The method of claim 1, wherein the production of the functional layer takes place by section-wise laser dispersion over at least one region of the side of the die plate base material, and wherein a region of up to 5 mm in diameter is heated by means of the laser beam.

4. The method according of claim 1, wherein the step of production of the functional layer is repeated several times.

5. A die plate of an extruder of a pelletizer for thermoplastic material, with die orifice openings comprising a functional layer with a reinforcing material disposed on at least one region of at least one side of the die plate, wherein the reinforcing material is embedded in a base material of the die plate.

6. The die plate of claim 5, wherein the reinforcing material is in the form of particles, and wherein the particles are embedded in the die plate base material in the functional layer.

7. The die plate of claim 6, wherein the die plate base material is a metal or metal alloy.

8. The die plate of claim 6, wherein the particles of the reinforcing material in the functional layer have an average diameter in the range of 0.5 μm to 2.0 μm.

9. The die plate of claim 6, wherein the particles of the reinforcing material in the functional layer have a content by volume in the range of 5 vol. % to 50 vol. %.

10. The die plate of claim 5, wherein the reinforcing material is a ceramic material.

11. The die plate of claim 5, wherein the reinforcing material is ZrO2.

12. The die plate of claim 5, wherein the reinforcing material is a carbide alloy.

13. The die plate of claim 5, wherein the functional layer has an average layer thickness of no more than 3 mm.

14. The die plate of claim 5, wherein the functional layer has a hardness in the range of 1000 HV to 1500 HV.

15. The die plate of claim 5, wherein the functional layer has a coefficient of thermal conductivity in the range of 1 W/mK to 2 W/mK.

16. The die plate of claim 5, wherein the functional layer has a coefficient of thermal expansion within the range of ±10% of the die plate.

17. A die plate manufactured by:
a. providing a die plate blank of a die plate base material;
b. producing a functional layer with a reinforcing material in at least one region on at least one side of the die plate blank, the reinforcing material being applied to the die plate base material in the region of the functional layer by laser dispersion; and
c. applying the die orifice openings to the die plate .

18. The die plate of claim 17, wherein the production of the functional layer by laser dispersion further comprises applying the reinforcing material at least section-wise as a particle powder to the die plate base material and heating at least the die plate at least in the region of the functional layer with the laser beam allowing the particles from the particle powder of the reinforcing material to embed in the die plate base material in the region of the heated functional layer.

19. The die plate of claim 17, wherein the production of the functional layer takes place by section-wise laser dispersion over at least one region of the side of the die plate base material, and wherein a region of up to 5 mm in diameter is heated by means of the laser beam.

20. The die plate of claim 17, wherein the particles of the reinforcing material in the functional layer have an average diameter in the range of 0.5 μm to 2.0 μm.
